(19) United States
(12) Patent Application Publication
(10) Pub. No.: US 2008/0311285 A1
(43) Pub. Date: Dec. 18, 2008

(54) CONTACT HOLE FORMING METHOD, CONDUCTING POST FORMING METHOD, WIRING PATTERN FORMING METHOD, MULTILAYERED WIRING SUBSTRATE PRODUCING METHOD, ELECTRO-OPTICAL DEVICE PRODUCING METHOD, AND ELECTRONIC APPARATUS PRODUCING METHOD

(75) Inventors: Toshimitsu Hirai, Hokuto (JP); Yasushi Takano, Matsumoto (JP)

Correspondence Address: HARNESS, DICKEY & PIERCE, P.L.C., P.O. BOX 828, BLOOMFIELD HILLS, MI, 48303, US

(73) Assignee: Seiko Epson Corporation, Tokyo (JP)

(21) Appl. No.: 12/138,012

(22) Filed: Jun. 12, 2008

(30) Foreign Application Priority Data
Jun. 14, 2007 (JP) 2007-157578
Apr. 22, 2008 (JP) 2008-111166

(51) Int. Cl. H05K 3/00; H01R 43/00

(52) U.S. Cl. 427/97.2; 29/885

(57) ABSTRACT

A method for forming a contact hole includes forming a lyophobic area by applying a liquid droplet of a lyophobic material on a region for forming a contact hole on a wiring, the lyophobic material being lyophobic to a liquid that contains an insulating layer forming material; and forming an insulating layer by applying a droplet of the liquid containing the insulating layer forming material so as to cover the wiring except for the lyophobic area, wherein the contact hole formed penetrates through the insulating layer to be connected to the wiring covered by the insulating layer.

### BACKGROUND

1. Technical Field

The present invention relates to a contact hole forming method, a conducting post forming method, a wiring pattern forming method, a multilayered wiring substrate producing method, an electro-optical device producing method, and an electronic apparatus producing method.

2. Related Art

When forming a pattern by a liquid droplet discharging method (an inkjet method), liquid droplets (ink) are emitted and landed at predetermined positions on a substrate. In this case, depending on characteristics of a substrate surface, the liquid droplets landed on the substrate are likely to spread wettingly to an excessive extent or are likely to be separated from each other. This does not result in a satisfactory formation of a wiring pattern intended.

Given such a problem, JP-A-2004-200244 discloses a technique in which after lyophobic processing is performed on a substrate surface for forming a pattern, a UV laser beam passing through a photo catalyst is irradiated on the lyophobic surface to form a lyophilic pattern.

Additionally, in a technique disclosed in JP-A-1999-344804, after applying a lyophobic base coat that contains a photocatalyst on a pattern forming substrate, the substrate is exposed to light via a mask to make only an exposed area lyophilic.

Meanwhile, when such wiring patterns are laminated to constitute a multilayered wiring structure, the wiring patterns are connected to each other via conducting posts provided in contact holes. In order to form the conducting posts (the contact holes), for example, JP-A-2003-282561 and JP-A-2006-140437 each discloses a technique in which liquid droplets containing an insulating material are applied and cured on a non-conducting post (non-contact hole) forming region provided on a first wiring so as to form an insulating layer, and then, liquid droplets containing a conductive material are applied and cured on a conducting-post forming region.

In the above related art techniques, however, there are problems as below.

Metal wirings particularly have a highly wettable surface. Thus, when the insulating-material containing liquid droplets are applied on the non-contact-hole (non-conducting-post) forming region, the droplets are easy to spread wettingly thereon. This makes it difficult to control such that a contact hole forming region (the conducting post forming region) has an intended size.

In addition, in order to form the wiring pattern, the former two techniques disclosed above use expensive tools such as an exposure apparatus, a photo mask, and a laser beam source, thus resulting in cost increase. Furthermore, a lyophobic material primarily required only on a non-pattern forming region is applied on an entire substrate surface. This is unfavorable from the standpoint of material consumption reduction.

### SUMMARY

An advantage of the present invention is to provide a contact hole forming method, a conducting post forming method, and a multilayered wiring substrate producing method, which are excellent in size control and enable high-quality wiring pattern formation without causing cost increase. Another advantage of the invention is to provide an electro-optical device producing method and an electronic apparatus producing method, which use the above multilayered wiring substrate.

In order to solve the above problems, a method for forming a contact hole according to a first aspect of the invention includes forming a lyophobic area by applying a liquid droplet of a lyophobic material on a region for forming a contact hole on a wiring, the lyophobic material being lyophobic to a liquid that contains an insulating layer forming material; and forming an insulating layer by applying a droplet of the liquid containing the insulating layer forming material so as to cover the wiring except for the lyophobic area, wherein the contact hole formed penetrates through the insulating layer to be connected to the wiring covered by the insulating layer.

In the contact hole forming method of the first aspect, the liquid droplet containing the insulting layer forming material is applied so as to cover the wiring except for the lyophobic area. In this situation, a lyophobic property of the lyophobic area allows the liquid droplet containing the insulating layer forming material to be repelled. This prevents the contact hole forming region from being covered by the insulating layer forming material, whereby the insulating layer has an opening equivalent to a size of the lyophobic area. As a result, there is formed a contact hole in which the wiring is exposed. Accordingly, the method of the first aspect enables the contact hole to be formed with an excellent controllability in accordance with the size of the lyophobic area.

Preferably, in the method of the first aspect, a diameter of the contact hole is adjusted by an amount of the lyophobic liquid droplet applied.

Thereby, in the above method, when the amount of the lyophobic liquid droplet applied or an amount of each droplet is fixed, adjusting a count of droplets applied can facilitate control of the diameter of the contact hole.

Additionally, in the method of the first aspect, the lyophobic area may be removed by O₂ plasma treatment or UV irradiation treatment.

In this case, adjusting an O₂ plasma treatment time or a UV irradiation time enables control of the lyophobic property of the lyophobic area (a contact angle of the liquid containing the insulating layer forming material on the lyophobic area).

Preferably, the lyophobic material includes at least one of a silane compound and a compound having a fluoroalkyl group. In this case, preferably, the silane compound forms a self-assembled film.

In addition, the lyophobic area can be formed on a surface of a substrate by using a self-assembled film made of the compound having the fluoroalkyl group.

Preferably, the lyophobic material includes a fluorine compound.

Preferably, the contact hole forming method of the first aspect further includes forming a plurality of for-wiring lyophobic areas by applying a liquid droplet of a second lyophobic material lyophobic to a liquid containing a wiring forming material on a non-wiring forming region on a wiring forming surface, the wiring forming surface being lyophilic to a droplet of the liquid that contains the wiring forming material, and forming the wiring by applying the liquid droplet containing the wiring forming material on a lyophilic area located between the for wiring lyophobic areas.

In this manner, in the contact hole forming method of the first aspect, the liquid droplet containing the wiring forming material is applied on the lyophilic surface for forming the wiring. Thereby, the liquid containing the wiring forming material repelled by the for-wiring lyophobic areas are retained on the lyophilic area between the for-wiring lyophobic areas. This enables the wiring in accordance with a location of the lyophilic area (namely, a location of the for-wiring lyophobic areas) to be formed with a high precision on the wiring forming surface. In addition, in the above method, the for-wiring lyophobic areas are formed into a pattern by applying the liquid droplet containing the second lyophobic material. Thus, it is unnecessary to use any expensive tool such as an exposure apparatus, a photo mask, or a laser beam source, thereby preventing cost increase.

A method for forming a conducting post according to a second aspect of the invention includes forming a contact hole by the method of the first aspect, and forming a conducting post by applying a liquid droplet containing a conductive material in the contact hole formed, the conducting post penetrating through an insulating layer to be connected to a wiring covered by the insulating layer.

In this manner, in the conducting post forming method of the second aspect, the liquid droplet containing the insulating layer forming material is applied so as to cover the wiring having the lyophobic area formed thereon, and then, is repelled by the lyophobic property of the lyophobic area. This prevents a conducting post forming region from being covered by the insulating layer forming material, whereby the insulating layer has an opening equivalent to a size of the lyophobic area, which results in formation of the contact hole in which the wiring is exposed. Then, the liquid droplet containing the conductive material is applied in the contact hole, which enables formation of the conducing post that is connected to the wiring to penetrate through the insulating layer.

Consequently, the method of the second aspect produces the conducting post, with the excellent controllability in accordance with the size of the lyophobic area.

Preferably, the conducting post forming method of the second aspect further includes irradiating energy light to the lyophobic area.

In this manner, in the method of the second aspect, the conductive-material containing liquid droplet is applied after reduction of the lyophobic property of the lyophobic area in addition to curing of the insulating layer. This enables formation of the conducting post connected to the wiring to penetrate through the insulating layer.

Preferably, the conducting post forming method of the second aspect further includes welding the wiring and the conducting post to each other by heating at least the lyophobic area and the conducting post.

In this manner, in the method of the second aspect, the lyophobic area does not inhibit electrical continuity between the wiring and the conducting post, thereby securing electrical connection the wiring and the conducting post.

A method for forming a wiring pattern according to a third aspect of the invention includes forming a contact hole by the method of the first aspect, curing an insulating layer, irradiating energy light to a lyophobic area and the insulating layer, and forming a second wiring extended over the insulating layer and the contact hole, the second wiring being connected to a first wiring covered by the insulating layer via the contact hole penetrating through the insulating layer.

In this manner, in the method of the third aspect, after curing the insulating layer having the opening equivalent to the size of the lyophobic area, the energy light is irradiated to the lyophobic area and the insulating layer to provide a lyophilic property to the area and the layer. Additionally, the second wiring is formed to extend over the lyophobic area and the insulating layer that have the lyophilic property. This enables formation of the second wiring connected to the first wiring via the contact hole having a size defined by the size of the lyophobic area.

Preferably, in the wiring pattern forming method of the third aspect, the second wiring is formed by applying a liquid droplet containing a conductive material on a second-wiring forming region that extends over the insulting layer and the contact hole.

In this manner, in the method of the third aspect, the conductive-material containing liquid droplet is applied on the second wiring forming region extending over the insulating layer and the contact hole by using a liquid droplet discharging method. This enables connection between the first and the second wirings via the conductive material applied in the contact hole having the defined size.

Preferably, the wiring pattern forming method of the third aspect further includes forming a plating catalyst layer by applying a liquid droplet containing a plating catalyst material on the second wiring forming region extending over the insulating layer and the contact hole, and forming the second wiring on the plating catalyst layer by plating treatment.

In this manner, in the method of the third aspect, after forming the plating catalyst layer on the second wiring forming region extending over the insulating layer and the contact hole by the liquid droplet discharging method, the plating treatment is performed, whereby the second wiring can be deposited on the plating catalyst layer. This enables formation of the second wiring that is elaborate and excellent in conductivity by being connected to the first wiring via the conductive material applied in the contact hole having the defined size.

A method for producing a multilayered wiring substrate according to a fourth aspect of the invention includes forming a contact hole by the method of the first aspect, laminating a first wiring and a second wiring via an insulating layer, and connecting the first and the second wirings to each other via the contact hole.

In this manner, the method of the fourth aspect enables production of a high-quality multilayered wiring substrate in which the size of the contact hole is set with the excellent controllability.

A method for producing an electro-optical device according to a fifth aspect of the invention uses the multilayered wiring substrate producing method of the fourth aspect.

In addition, a method for producing an electronic apparatus according to a sixth aspect of the invention uses the multilayered wiring substrate producing method of the fourth aspect.

In this manner, in the methods of the fifth and the sixth aspects, using the high-quality multilayered wiring substrate enables productions of a high-quality electro-optical device and a high-quality electronic apparatus.

### BRIEF DESCRIPTION OF THE DRAWINGS

The invention will be described with reference to the accompanying drawings, wherein like numbers reference like elements.

FIG. 1 is a schematic structural view of a liquid droplet discharging apparatus.

FIG. 2 is a sectional view of a liquid droplet discharging head 301.

FIG. 3 is a schematic structural view of a multilayered wiring substrate according to a first embodiment of the invention.

FIGS. 4A and 4B are illustrations showing lyophobic areas and wiring patterns formed on the substrate.

FIGS. 5A and 5B are illustrations showing a pattern forming method.

FIGS. 6A and 6B are illustrations showing the pattern forming method.

FIGS. 7A and 7B are illustrations showing the pattern forming method.

FIG. 8 is a table showing a relationship among contact angles on the lyophobic area and a lyophilic area, contrasts, and drawing results.

FIGS. 9A, 9B, and 9C are illustrations showing steps for forming a conducting post.

FIGS. 10A, 10B, and 10C are illustrations showing steps for a wiring pattern forming method according to a first embodiment.

FIGS. 11A, 11B, and 11C are illustrations showing steps for a wiring pattern forming method according to a second embodiment.

FIGS. 12A, 12B, and 12C are illustrations showing steps for the wiring pattern forming method according to the second embodiment.

FIGS. 13A, 13B, and 13C are illustrations showing steps for the wiring pattern forming method according to the second embodiment.

FIG. 14 is a sectional view showing a schematic structure of a multilayered wiring substrate according to a second embodiment.

FIG. 15 is an enlarged view showing a sectional structure of a display region of an organic electroluminescent (EL) device 100.

FIGS. 16A, 16B, and 16C are diagrams showing concrete examples of an electronic apparatus.

### DESCRIPTION OF EXEMPLARY EMBODIMENTS

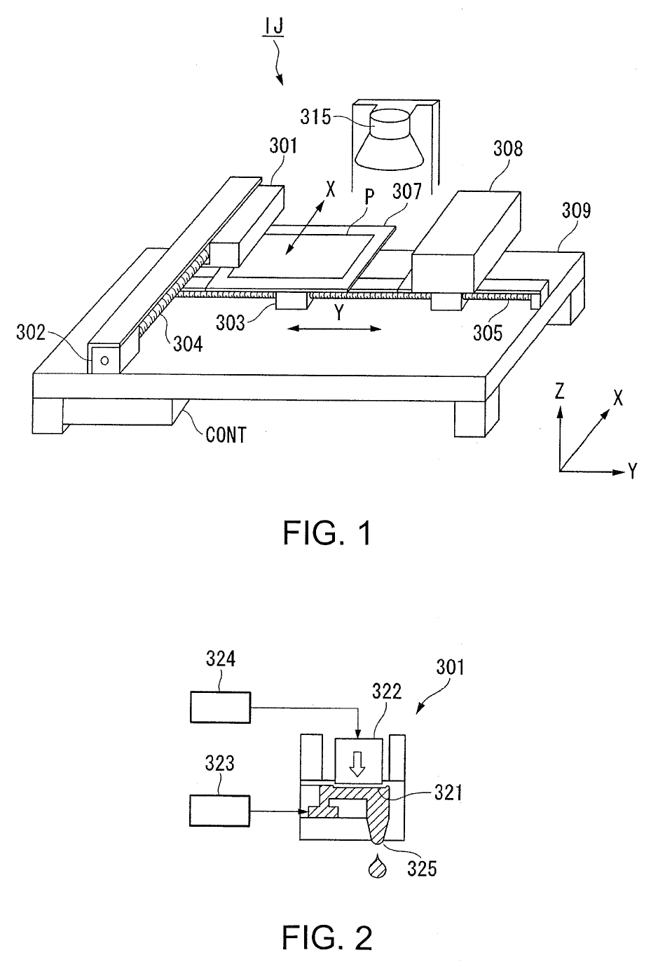

Hereinafter, embodiments of the present invention will be described by referring to FIGS. 1 to 16C.

In each of the drawings used for the description below, reduction scales of respective constituent members are changed as needed to allow the members to be recognizable.

Liquid Droplet Discharging Apparatus

First will be described a liquid droplet discharging apparatus used for a pattern forming method according to an embodiment.

FIG. 1 is a schematic structural view of the liquid droplet discharging apparatus, which is denoted by symbol “IJ”.

The liquid droplet discharging apparatus IJ discharges (drops) a liquid droplet on a substrate P from a liquid droplet discharging head. The liquid droplet discharging apparatus IJ includes a liquid droplet discharging head 301, an X-direction driving axis 304, a Y-direction guide axis 305, a controlling device CONT, a stage 307, a cleaning mechanism 308, a base 309, and a heater 315. The stage 307 supports the substrate P on which ink (a liquid material) is provided by the liquid droplet discharging apparatus IJ. The state 307 includes a not-shown fixing mechanism that fixes the substrate P to a reference position.

The liquid droplet discharging head 301 is of a multi-nozzle type having a plurality of discharging nozzles, and a longitudinal direction of the head corresponds to an X-axis direction. The discharging nozzles are arranged at an equal distance from each other in the X-axis direction on a lower surface of the liquid droplet discharging head 301. The discharging nozzles of the liquid droplet discharging head 301 discharge the above ink containing conductive microparticles on the substrate P supported by the stage 307.

The X-direction driving axis 304 is connected to an X-direction driving motor 302. The X-direction driving motor 302 is a stepping motor or the like and rotates the X-direction driving axis 304 when an X-direction driving signal is supplied from the controlling device CONT. When the X-direction driving axis 304 is rotated, the liquid droplet discharging head 301 is moved in the X-axis direction.

The Y-direction guide axis 305 is immovably fixed to the base 309. The stage 307 includes a Y-direction driving motor 303. The Y-direction driving motor 303 is a stepping motor or the like, and moves the stage 307 in a Y direction when a Y-direction driving signal is supplied from the controlling device CONT.

The controlling device CONT supplies a voltage for controlling the discharging of the liquid droplet to the liquid droplet discharging head 301. Additionally, the controlling device CONT supplies a driving pulse signal controlling an X-direction movement of the liquid droplet discharging head 301 to the X-direction driving motor 302, and supplies a driving pulse signal controlling a Y-direction movement of the stage 307 to the Y-direction driving motor 303.

The cleaning mechanism 308 cleans the liquid droplet discharging head 301 and includes a not-shown Y-direction driving motor. Driving the Y-direction driving motor allows the cleaning mechanism to move along the Y-direction guide axis 305. The controlling device CONT controls a movement of the cleaning mechanism 308.

The heater 315 is a unit that thermally processes the substrate P by lamp annealing to evaporate and dry a solvent contained in the liquid material applied on the substrate P. The controlling device CONT also controls turning on and turning off of the heater 315.

The liquid droplet discharging apparatus IJ discharges liquid droplets on the substrate P while causing relative scanning movement between the liquid droplet discharging head 301 and the stage 307 supporting the substrate P. In this case, in the description below, the X direction represents a non-scanning direction and the Y direction orthogonal to the X direction represents a scanning direction.

Thus, the discharging nozzles of the liquid droplet discharging head 301 are arranged at a constant distance from each other in the X direction as the non-scanning direction. In FIG. 1, the liquid droplet discharging head 301 is arranged perpendicular to a moving direction of the substrate P. However, an angle of the liquid droplet discharging head 301 may be adjusted to intersect with the moving direction of the substrate P. In this manner, adjusting the angle of the liquid droplet discharging head 301 allows adjustment of a pitch between the nozzles. Additionally, a distance between the substrate P and a nozzle surface may be arbitrarily adjusted.

FIG. 2 is a sectional view of the liquid droplet discharging head 301.

The liquid droplet discharging head 301 includes a piezo element 322 adjacent to a liquid chamber 321 that stores the liquid material (such as wiring ink). The liquid material is supplied to the liquid chamber 321 via a liquid material supplying system 323 that includes a material tank storing the liquid material.

The piezo element 322 is connected to a driving circuit 324 via which a voltage is applied to the piezo element 322 to deform the element. This causes deformation of the liquid chamber 321, thereby causing the liquid material to be discharged from the nozzles 325.

In this case, a value of the voltage applied is changed to control a distortion amount of the piezo element 322. Additionally, a frequency of the applied voltage is changed to control a distortion rate of the piezo element 322. A liquid droplet discharging method using a piezo system does not apply heat to the material. Therefore, the method has an advantage that there is hardly any influence on a composition of the material.

Other than an electro-mechanical conversion system as described above, examples of a discharging technique of the liquid droplet discharging method include an electrification control system, a pressure-applying vibration system, an electro-thermal conversion system, and an electrostatic attraction system. In the electrification control system, electric charge is applied to a material by a charging electrode, and a flying direction of the material is controlled by a deflecting electrode, whereby the material is discharged from nozzles. In the pressure-applying vibration system, for example, an ultra-high voltage of approximately 30 kg/cm² is applied to a material to discharge the material toward a tip portion of a nozzle. When no control voltage is applied, the material moves straightly to be discharged from the nozzle. When a control voltage is applied, electrostatic repulsion occurs in material particles, so that the material is scattered and not discharged from the nozzle.

Additionally, in the electro-thermal conversion system, a heater provided in a material-storing space is used to rapidly evaporate a material to generate bubbles, whereby the material in the space is discharged by a pressure of the bubbles. In the electrostatic attraction system, a minute pressure is applied into the material-storing space to form a meniscus of the material in a nozzle. In that condition, electrostatic attraction is applied to draw out the material. Other than those, it is also possible to apply techniques such as a system that uses viscosity change of a liquid by an electric field and a system that makes a material fly by discharging sparks. The liquid droplet discharging method has advantages that there is no waste in the use of the material, as well as an intended amount of the material can be appropriately provided at an intended position. An amount of a single droplet of the liquid material (a fluid) discharged by using the liquid droplet discharging method may be in a range of 1 to 300 nanograms, for example.

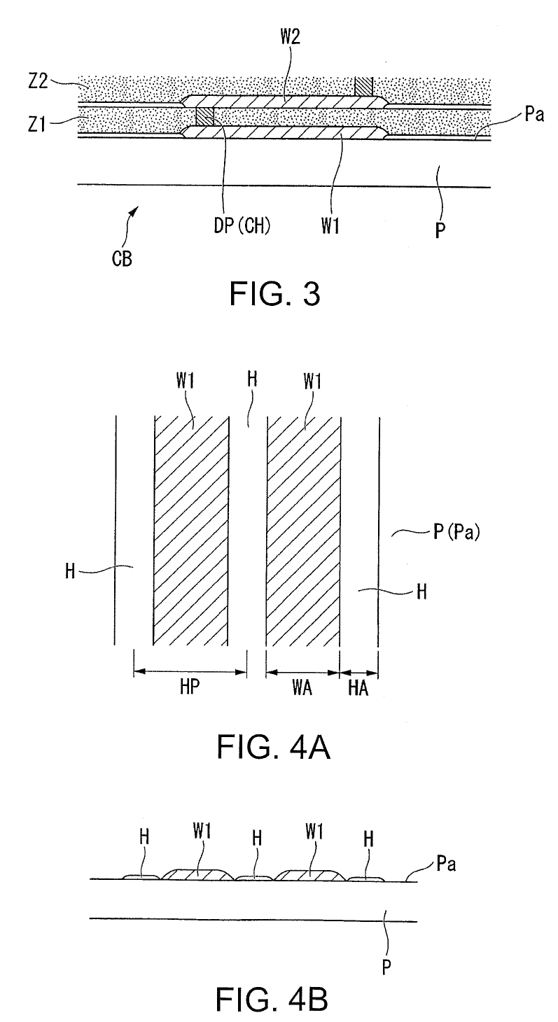

Next will be described a contact hole forming method and a conducting post forming method performed by using the liquid droplet discharging apparatus IJ, with reference to FIGS. 3 to 9C.

As shown in FIG. 3, a description below will be given of a production of a multilayered wiring substrate having a plurality of layers of wirings formed thereon, according to a first embodiment of the invention.

A multilayered wiring substrate CB in FIG. 3 includes a wiring pattern (a first wiring) W1 formed on the substrate P where at least a surface Pa has a lyophilic property as a lyophilic area, and a wiring pattern (a second wiring) W2 formed on an insulating layer Z1 that is made of acryl or the like and that covers the wiring pattern W1. The wiring patterns W1 and W2 are electrically connected to each other by a conducting post DP provided in a contact hole CH that penetrates through the insulating layer Z1. The wiring pattern W2 is covered by an insulating layer Z2 and also is connected to multilayered wiring patterns by conducting posts. A description of other layers over the insulating layer Z2 will be omitted.

The substrate P may be made of a material such as glass, quartz glass, a silicon wafer, a plastic film, a metal plate, or polyimide. On a surface of the substrate P, there may be formed an underlayer made of a semiconductor film, a metal film, a dielectric film, an organic film, or the like.

First will be described a method for forming the wiring pattern W1 on the substrate P.

In the description, as shown in FIGS. 4A and 4B, a plurality of (three in the embodiment) linear lyophobic areas H is provided at a distance from each other, and the wiring pattern W1 having a conductive property is formed between the lyophobic areas H. The lyophobic areas described in the embodiment represent areas on which a contact angle of a conductive-material containing liquid droplet (hereinafter referred to as a “pattern liquid droplet”) is maintained at a predetermined value or larger. Meanwhile, on the lyophilic area, the contact angle of the conductive-material containing liquid droplet is maintained at a predetermined value or smaller.

The wiring pattern W1 is formed by applying an ink droplet for the wiring pattern as above on the substrate P. Namely, for example, the wiring pattern W1 is schematically formed by a surface treatment process, a lyophobic area forming process, a material arrangement process, and a thermal treatment and/or optical treatment process.

Hereinafter, each process will be described in detail.

Surface Treatment Process

In the surface treatment process, the surface Pa of the substrate P is cleaned to increase the lyophilic property of the surface.

For example, when the substrate P is made of glass, the glass substrate has a surface lyophilic to a wiring pattern forming material (ink). Then, the above surface cleaning treatment further increases the lyophilic property of the surface Pa of the substrate P.

Specifically, in the surface treatment process, examples of the surface cleaning treatment include excimer UV cleaning, low-pressure mercury lamp cleaning, O₂ plasma cleaning, acid cleaning by using hydrofluoric acid (HF), sulfuric acid, or the like, alkali cleaning, ultrasonic cleaning, megasonic cleaning, corona cleaning, glow cleaning, scrub cleaning, ozone cleaning, hydrogen water cleaning, microbubble cleaning, and fluorine cleaning.

When a contact angle of the pattern liquid droplet on the surface Pa (the lyophilic area) is larger than 25 degrees, a bulge (a liquid lump) tends to occur, whereas when the contact angle thereof is 20 degrees or smaller, no bulge occurs. Accordingly, in the present embodiment, cleaning conditions are adjusted such that the contact angle of the pattern liquid droplet on the substrate surface Pa is 20 degrees or smaller.

Specifically, for example, when using the excimer UV cleaning, the cleaning conditions can be adjusted by a combination of a UV light irradiation time, an irradiation intensity, an irradiation frequency, a thermal treatment (heating), and the like. Additionally, for example, when the O₂ plasma cleaning is used as the cleaning treatment, the lyophilic property (the contact angle) can be adjusted by an adjustment of a plasma treatment time. The above cleaning treatments enable removal of a foreign substance such as an organic material on the surface Pa, so that a high degree of cleaning and a high degree of a lyophilic property can be maintained.

Lyophobic Area Forming Process

Next, the lyophobic area (a for-wiring lyophobic area) H will be formed on a predetermined region (a periphery of the region having the pattern W1 formed thereon: a non-wiring region) of the surface (a wiring forming surface) Pa of the substrate P that has been subjected to the cleaning treatment process (a lyophilic treatment).

Specifically, the liquid droplet discharging apparatus IJ discharges a liquid droplet from the liquid droplet discharging head 301 to apply on a predetermined region of the substrate P. The liquid droplet applied (hereinafter referred to as a “lyophobic liquid droplet”) contains a material lyophobic to the pattern liquid droplet, namely, a second lyophobic material.

Examples of the lyophobic material to be used include silane compounds, fluoroalkyl group-containing compounds, fluororesins (fluorine-containing resins), and mixtures of those compounds.

The silane compounds are expressed by a general formula (1):

R¹SiX¹ₘX²₍₃₋ₘ₎ (1)

In the above formula, R¹ represents an organic group; X¹ and X² represent —OR², —R², or —Cl; R² represents an alkyl group having a number of carbons ranging from 1 to 4; and m represents an integer ranging from 1 to 3. The lyophobic material to be used can be a single kind or two or more kinds of the silane compounds (a component A) expressed by the formula (1).

In the silane compounds expressed by the general formula (1), a silane atom is substituted by an organic group, and other bonding groups are substituted by alkoxy groups, alkyl groups, or chlorine groups. For example, the organic group R¹ may be a phenyl group, a benzyl group, a phenethyl group, a hydroxyphenyl group, a chlorophenyl group, an aminophenyl group, a naphthyl group, a thianthrenyl group, a pyrenyl group, a thienyl group, a pyrrolyl group, a cyclohexyl group, a cyclohexenyl group, a cyclopentyl group, a cyclopentenyl group, a pyridinyl group, a methyl group, an ethyl group, an n-propyl group, an isopropyl group, an n-butyl group, an isobutyl group, a sec-butyl group, a tert-butyl group, an octadecyl group, an n-octyl group, a chloromethyl group, a methoxyethyl group, a hydroxyethyl group, an aminoethyl group, a cyano group, a mercaptopropyl group, a vinyl group, an allyl group, an acryloxyethyl group, a metacryloxyethyl group, a glycydoxypropyl group, or an acetoxy group.

Additionally, X¹ is an alkoxy group, a chlorine group, or a functional group that forms an Si—O—Si bond or the like, and is hydrolyzed with water and desorbed as an alcohol or an acid. Examples of the alkoxy group include a methoxy group, an ethoxy group, an n-propoxy group, an isopropoxy group, an n-butoxy group, an isobutoxy group, a sec-butoxy group, and a tert-butoxy group.

The number of carbons of R² is preferably in the range of 1 to 4 from a standpoint that desorbed alcohol molecules have a relatively small molecular weight and thus can be easily removed, as well as a density reduction of a film to be formed can be suppressed.

The silane compounds expressed by the general formula (1) may be dimethyl dimethoxysilane, diethyl diethoxysilane, 1-propenylmethyldichlorosilane, propyldimethyldichlorosilane, propylmethyldichlorosilane, propyltrichlorosilane, propyltriethoxysilane, propyltrimethoxysilane, styrylethyl trimethoxysilane, tetradecyl trichlrosilane, 3-thiocyanate propyltriethoxysilane, p-tolyldimethylchlorosilane, p-tolylmethyldichlorosilane, p-tolyltrichlorosilane, p-tolyltrimethoxysilane, p-tolyltriethoxysilane, di-n-propyldi-n-propoxysilane, diisopropyl diisopropoxysilane, di-n-butyldi-n-butyloxysilane, di-sec-butyldi-sec-butyloxysilane, di-t-butyldi-t-butyloxysilane, octadecyltrichlorosilane, octadecylmethyl diethoxysilane, octadecyltriethoxysilane, octadecyltrimethoxysilane (ODS), octadecyldimethylchlorosilane, octadecylmethyldichlorosilane, octadecylmethoxydichlorosilane, 7-octenyl dimethylchlorosilane, 7-octenyl trichlorosilane, 7-octenyl trimethoxysilane, octylmethyldichlorosilane, octyldimethylchlorosilane, octyltrichlorosilane, 10-undecynyldimethychlorosilane, undecyltrichlorosilane, vinyldimethylchlorosilane, methyloctadecyldimethoxysilane, methyldodecyldiethoxysilane, methyloctadecyldimethoxysilane, methyloctadecyldiethoxysilane, n-octylmethyldimethixysilane, n-octylmethyldiethoxysilane, triaconttyldimethylchlorosilane, triaconttyltrichlorosilane, methyltrimethoxysilane, methyltriethoxysilane, methyltri-n-propoxysilane, methylisopropoxysilane, methyl n-butyloxysilane, methyltri-sec-butyloxysilane, methyltri-t-butyloxysilane, ethyltrimethoxysilane, ethyltriethoxysilane, ethyltri-n-propoxysilane, ethylisopropoxysilane, ethyl-n-butyloxysilane, ethyltri-sec-butyloxysilane, ethyltri-t-butyloxysilane, n-propyltrimethoxysilane, isobutyltrimethoxysilane, n-hexyltrimethoxysilane, hexadecyltrimethoxysilane, n-octyltrimethoxysilane, n-dodecyltrimethoxysilane, n-octadecyltrimethoxysilane, n-propyltriethoxysilane, isobutyltriethoxysilane, n-hexyltriethoxysilane, hexadecyltriethoxysilane, n-octyltriethoxysilane, n-dodecyltrimethoxysilane, n-octadecyltriethoxysilane, 2-[2-(trichlorosily)ethyl]pyridine, 4-[2-(trichlorosilyl)ethyl]pyridine, diphenyldimethoxysilane, diphenyldiethoxysilane, 1,3-(trichlorosilylmethyl)heptacosane, dibenzyldimethoxysilane, dibenzyldiethoxysilane, phenyltrimethoxysilane, phenylmethyldimethoxysilane, phenyldimethylmethoxysilane, phenyldimethoxysilane, phenyldiethoxysilane, phenylmethyldiethoxysilane, phenyldimethylethoxysilane, benzyltriethoxysilane, benzyltrimethoxysilane, benzylmethyldimethoxysilane, benzyldimethylmethoxysilane, benzyldimethoxysilane, benzyldiethoxysilane, benzylmethyldiethoxysilane, benzyldimethylethoxysilane, benzyltriethoxysilane, dibenzyldimethoxysilane, dibenzyldiethoxysilane, 3-acetoxypropyltrimethoxysilane, 3-acryloxypropyltrimethoxysilane, aryltrimethoxysilane, aryltriethoxysilane, 4-aminobutyltriethoxysilane, (aminoethylaminomethyl)phenethyltrimethoxysilane, N-(2-aminoethyl)-3-aminopropylmethyldimethoxysilane, N-(2-aminoethyl)-3-aminopropyltrimethoxysilane, 6-(aminohexylaminopropyl)trimethoxysilane, p-aminophenyltrimethoxysilane, p-aminophenylethoxysilane, m-aminophenyltrimethoxysilane, m-aminophenylethoxysilane, 3-aminopropyltrimethoxysilane, 3-aminopropyltriethoxysilane, ω-aminoundecyltrimethoxysilane, amyltriethoxysilane, benzoxasilepin dimethylester, 5-(bicycloheptenyl)triethoxysilane, bis(2-hydroxyethyl)-3-aminopropyltriethoxysilane, 8-bromooctyltrimethoxysilane, bromophenyltrimethoxysilane, 3-bromopropyltrimethoxysilane, n-butyltrimethoxysilane, 2-chloromethyltriethoxysilane, chloromethylmethyldiethoxysilane, chloromethylmethyldiisopropxysilane, p-(chloromethyl)phenyltrimethoxysilane, chloromethyltriethoxysilane, chlorophenyltriethoxysilane, 3-chloropropylmethyldimethoxysilane, 3-chloropropyltriethoxysilane, 3-chloropropyltrimethoxysilane, 2-(4-chlorosulfonylphenyl)ethyltrimethoxysilane, 2-cyanoethyltriethoxysilane, 2-cyanoethyltrimethoxysilane, cyanomethylphenethyltriethoxysilane, 3-cyanopropyltriethoxysilane, 2-(3-cyclohexenyl)ethyltrimethoxysilane, 2-(3-cyclohexenyl)ethyltriethoxysilane, 3-cyclohexenyltrichlorosilane, 2-(3-cyclohexenyl)ethyltrichlorosilane, 2-(3-cyclohexenyl)ethyldimethylchlorosilane, 2-(3-cyclohexyenyl)ethylmethyldichlorosilane, cyclohexyldimethylchlorosilane, cyclohexylethyldimethoxysilane, cyclohexylmethyldichlorosilane, cyclohexylmethyldimethoxysilane, (cyclohexylmethyl)trichlorosilane, cyclohexyltrichlorosilane, cyclohexyltrimethoxysilane, cyclooctyltrichlorosilane, (4-cyclooctenyl)trichlorosilane, cyclopentyltrichlorosilane, cyclopentyltrimethoxysilane, 1,1-diethoxy-1-silacyclopenta-3-ene, 3-(2,4-dinitrophenylamino)propyltriethoxysilane, (dimethylchlorosilyl)methyl-7,7-dimethylnorphinane, (cyclohexylaminomethyl)methyldiethoxysilane, (3-cyclopentadienylpropyl)triethoxysilane, (N, N-diethyl-3-aminopropyl)trimethoxysilane, 2-(3,4-epoxycyclohexyl)ethyltrimethoxysilane, 2-(3,4-epoxycyclohexyl)ethyltriethoxysilane, (furfuryloxymethyl)triethoxysilane, 2-hydroxy-4-(3triethoxypropoxy)diphenylketone, 3-(p-methoxyphenyl)propylmethyldichlorosilane, 3-(p-methoxyphenyl)propyltrichlorosilane, p-(methylphenethyl)methyldichlorosilane, p-(methylphenethyl)trichlorosilane, p-(methylphenethyl)dimethylchlorosilane, 3-morpholinopropyltrimethoxysilane, (3-glycidoxypropyl)methyldiethoxysilane, 3-glycidoxypropyltrimethoxysilane, 1,2,3,4,7,7,-hexachloro-6-methyldiethoxysilyl-2-norbornene, 1,2,3,4,7,7,-hexachloro-6-triethoxysilyl2-norbornene, 3-iodo propyltrimethoxysilane, 3-isocyanatepropyltriethoxysilane, (mercaptomethyl)methyldiethoxysilane, 3-mercaptopropylmethyldimethoxysilane, 3-mercaptopropyldimethoxysilane, 3-mercaptopropyltriethoxysilane, 3-methacryloxypropylmethyldiethoxysilane, 3-methacryloxypropyltrimethoxysilane, methy{2-(3-trimethoxysilylpropylamino)ethylamino}-3-propyonate, 7-octenyltrimethoxysilane, R—N-α-phenethyl-N′-triethoxysilylpropylurea, S—N-α-phenethyl N′-triethoxysilylpropylurea, phenethyltrimethoxysilane, phenethylmethyldimethoxysilane, phenethyldimethylmethoxysilane, phenethyldimethoxysilane, phenethyldiethoxysilane, phenethylmethyldiethoxysilane, phenethyldimethylethoxysilane, phenethyltriethoxysilane, (3-phenylpropyl)dimethylchlorosilane, (3-phenylpropyl)methyldichlorosilane, N-phenylaminopropyltrimethoxysilane, N-(triethoxysilylpropyl)dansylamide, N-(3-triethoxysilylpropyl)-4,5-dihydroimidazole, 2-(triethoxysilylethyl)-5-(chloroacetoxy)bicycloheptane, (S)-N-triethoxysilylpropyl-o -menthocarbamate, 3-(triethoxysilylpropyl)-p-nitrobenzamide, 3-(triethoxysilyl)propylsaccininc anhydride, N-[5-(trimethoxysilyl)-2-aza-1-oxo-pentyl]caprolactam, 2-(trimethoxysilylethyl)pyridine, N-(trimethoxysilylethyl)benzyl-N,N,N-trimethylammoniumchloride, phenylvinyldiethoxysilane, 3-thiocyanatepropyltriethoxysilane, (tridecafluoro-1,1,2,2,-tetrahydrooctyl)triethoxysilane, N-{3-(triethoxysilyl)propyl}phthalamic acid, (3,3,3-trifluoropropyl)methyldimethoxysilane, (3,3,3-trifluoropropyl)trimethoxysilane, 1-trimethoxysilyl-2-(chloromethyl)phenylethane, 2-(trimethoxysilyl)ethylphenylsulfonylazide, β-trimethoxysilylethyl-2-pyridine, trimethoxysilylpropyldiethylenetriamine, N-(3-trimethoxysilylpropyl)pyrrole, N-trimethoxysilylpropyl-N,N,N-trimethoxysilylpropyl-N,N,N-tributylammoniumbromide, N-trimethoxysilylpropyl-N,N,N-tributylammoniumchloride, N-trimethoxysilylpropyl-N,N,N-trimethylammoniumchloride, vinylmethyldiethoxysilane, vinyltriethoxysilane, vinyltrimethoxysilane, vinylmethyldimethoxysilane, vinyldimethylmethoxysilane, vinyldimethylethoxysilane, vinylmethyldichlorosilane, vinylphenyldichlorosilane, vinylphenyldiethoxysilane, vinylphenyldimethylsilane, vinylphenylmethylchlorosilane, vinyltriphenoxysilane, vinyltris-t-butoxysilane, adamantylethyltrichlorosilane, arylphenyltrichlorosilane, (aminoethylaminomethyl)phenethyltrimethoxysilane, 3-aminophenoxydimethylvinylsilane, phenyltrichlorosilane, phenyldimethylchlorosilane, phenylmethyldichlorosilane, benzyltrichlorosilane, benzyldimethylchlorosilane, benzylmethyldichlorosilane, phenethyldiisopropylchlorosilane, phenethyltrichlorosilane, phenethyldimethylchlorosilane, phenethylmethyldichlorosilane, 5-(bicycloheptenyl)trichorosilane, 5-(bicycloheptenyl)triethoxysilane, 2-(bicycloheptyl)dimethylchlorosilane, 2-(bicycloheptyl)trichlorosilane, 1,4-bis(trimethoxysilylethyl)benzene, bromophenyltrichlorosilane, 3-phenoxypropyldimethylchlorosilane, 3-phenoxypropyltrichlorosilane, t-butylphenylchlorosilane, t-butylphenylmethoxysilane, t-butylphenyldichlorosilane, p-(t-butyl)phenethyldimethylchlorosilane, p-(t-butyl)phenethyltrichlorosilane, 1,3-(chlorodimethylsilylmethyl)heptacosane, ((chloromethyl)phenylethyl) dimethylchlorosilane, ((chloromethyl)phenylethyl)methyldichlorosilane, ((chloromethyl)phenylethyl)trichlorosilane, ((chloromethyl)phenylethyl)trimethoxysilane, chlorophenyltrichlorosilane, 2-cyanoethyltrichlorosilane, 2-cyanoethylmethyldichlorosilane, 3-cyanopropylmethyldiethoxysilane, 3-cyanopropylmethyldichlorosilane, 3-cyanopropylmethyldichlorosilane, 3-cyanopropyldimethylethoxysilane, and 3-cyanopropyltrichlorosilane.

The fluorine-containing silane compound (a lyophobic silane compound) may be a fluorine-containing alkyl silane compound, namely, a compound having a structure represented by perfluoroalkyl structure CnF₂ₙ₊₁ bonded with Si. Examples of the fluorine-containing silane compound can be expressed by a general formula (2) below. In the formula (2), n represents an integer ranging from 1 to 18, and m represents an integer ranging from 2 to 6. Additionally, X¹ and X² represent —OR¹, —R², or —Cl; R² included in X¹ and X² represents an alkyl group having a number of carbons ranging from 1 to 4; and a represents an integer ranging from 1 to 3.

CₙF₂ₙ₊₁(CH₂)ₘSiX¹ₐX²₍₃₋ₐ₎ (2)

In the above formula (2), X¹ is an alkoxy group, a chlorine group, or a functional group that forms an Si—O—Si bond or the like and is hydrolyzed with water and desorbed as an alcohol or an acid. For example, the alkoxy group may be a methoxy group, an ethoxy group, an n-propoxy group, an isopropoxy group, an n-butoxy group, an n-isobutoxy group, a sec-butoxy group, or a tert-butoxy group.

Preferably, R² has the carbon number of 1 to 4 from the same standpoint as in the formula (1).

With the use of the fluorine-containing alkyl silane compound, each compound is aligned such that a fluoroalkyl group is positioned on a film surface, thereby forming a self-assembled film. This can allow the film surface to be evenly lyophobic.

More specifically, there may be mentioned CF₃—CH₂CH₂—Si(OCH₃)₃, CF₃(CF₂)₃—CH₂H₂—Si(OCH₃)₃, CF₃(CF₂)₅—CH₂CH₂—Si(OCH₃)₃, CF₃(CF₂)₅—CH₂CH₂—Si(OC₂H₅)₃, CF₃(CF₂)₇—CH₂CH₂—Si(OC H₃)₃, CF₃(CF₂)₁₁—CH₂CH₂ —Si(OC₂H₅)₃, CF₃ (CF₂)₃—CH₂CH₂—Si(CH₃)(OCH₃)₂, CF₃(CF₂)₇—CH₂CH₂—Si(CH₃)(OCH₃)₂, CF₃(CF₂)₈—CH₂CH₂—Si(CH₃)(OC₂H₅)₂, CF₃(CF₂)₈—CH₂CH₂ —Si(C₂H₅)(OC₂H₅)₂, and the like.

When fluororesin is used to form the lyophobic area H, a predetermined amount of fluororesins is dissolved in a predetermined solvent. Specifically, there may be used a solution prepared by dissolving 0.1 wt % of fluororesin in a hydrofluoroether (HFE) solvent (“EGC-1720” manufactured by Sumitomo 3M Ltd.). In this case, an appropriate amount of a solution of hydrocarbon, ketone, ether, or ester is mixed in the HFE solvent to thereby enable adjustment such that the liquid material is stably discharged from the liquid droplet discharging head 301. Other than that, the fluororesins to be used may be “lumiflon” (soluble in various kinds of solvents) manufactured by Asahi Glass Co., Ltd., “optool” (solvents: PFC, HFE, etc.) manufactured by Daikin Industries, Ltd., “dicguard” (solvents: toluene, water, and ethylene glycol) manufactured by Dainippon Ink & Chemicals, Inc., and the like.

In addition, it is also possible to use the fluorine-containing resin having a fluoro group, —CF₃, —CF₂—, —F₂ CF₃, —(CF₂)ₙCF₃, or —CF₂CFCl—, at a side chain thereof.

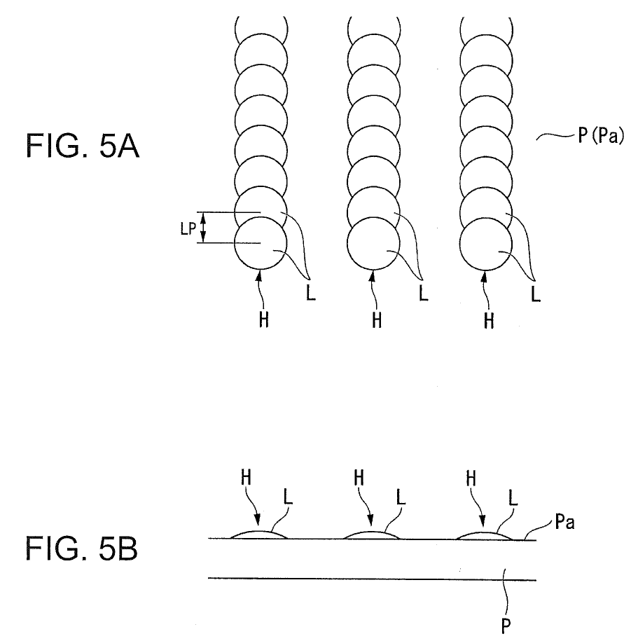

As shown in FIGS. 5A and 5B, the liquid droplet discharging head 301 continuously discharges lyophobic liquid droplets L containing the above lyophobic material on each of the lyophobic areas H.

On each lyophobic area H, the lyophobic liquid droplets L landed on the surface Pa of the substrate P are discharged and applied at positions where mutually adjacent liquid droplets L overlap with each other. Thereby, each lyophobic area H is formed with the droplets L applied by a single scanning operation of the liquid droplet discharging head 301 and the substrate.

In this case, as shown in FIG. 4A, a width WA of the wiring pattern W1 is determined by a difference between an arrangement pitch HP of the lyophobic areas H and a width HA of each lyophobic area H. Since the arrangement pitch HP is determined as a specification for the wiring pattern W1, the width WA of the wiring pattern W1 is dependent on the widths HA of the lyophobic areas H. The width HA of each of the lyophobic areas H is controlled by an amount of the lyophobic liquid droplet L discharged from the liquid droplet discharging head 301 and a discharging pitch LP shown in FIG. 5A.

Specifically, for example, it is supposed that the liquid droplets L are discharged in two different amounts La and Lb (e.g. La=2.5 pl and Lb=4.5 pl). Then, when the amounts La and Lb of the liquid droplets L are discharged and applied with the discharging pitch LP of each of 10, 20, and 30 μm, there is obtained a table in which the width HA of the lyophobic area H formed on the substrate P corresponds to each of the discharging amounts La, Lb and each of the discharging pitches LP. Thus, in order to form the lyophobic area H with the width HA to be intended, the table is accessed to select the discharging amount and the discharging pitch LP corresponding to the intended width HA. In a process of discharging the lyophobic liquid droplets, the liquid droplets L are discharged with the amount and the pitch LP selected.

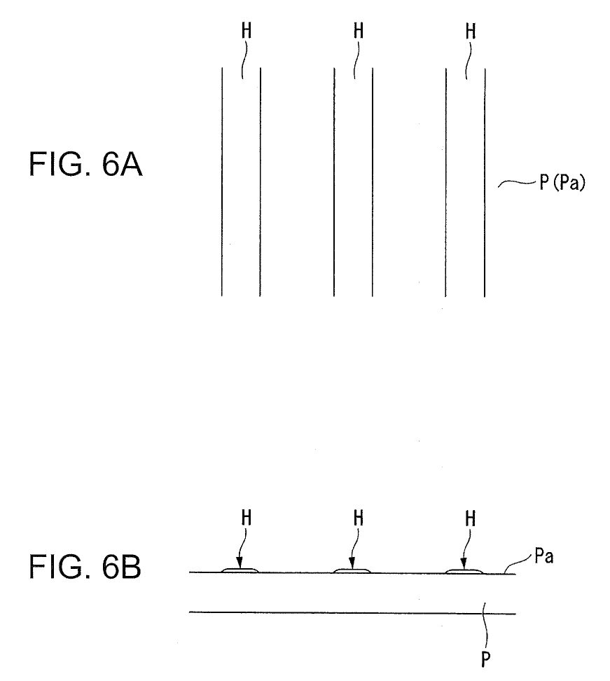

Next, the lyophobic liquid droplets L discharged on the substrate P are preliminarily dried, and as shown in FIGS. 6A and 6B, the lyophobic areas H each having a linear shape are formed to be spaced from each other on the substrate P, with a thickness of a few to a few tens of nanometers.

The lyophobic areas are made of the lyophobic material mentioned above, and thereby the contact angle of the pattern liquid droplet on the lyophobic area is set to 50 degrees or larger. Thus, a contrast (a difference of the contact angles) on the lyophilic area (the surface) Pa and the lyophobic area H is 30 degrees or larger.

Material Arrangement Process

Next, the pattern liquid droplet will be discharged between the lyophobic areas H on the surface Pa of the substrate P to form the wiring pattern W1.

In general, the wiring pattern is made of a dispersion liquid that contains conductive microparticles dispersed in a dispersion medium. In the present embodiment, the conductive microparticles may be metal microparticles containing any of gold, silver, copper, palladium, nickel, and ITO, or any of oxides thereof, microparticles of a conductive polymer, microparticles of a superconductor material, or the like.

Additionally, those microparticles can be used by coating surfaces of the particles with an organic substance to increase dispersibility. Preferably, a particle diameter of the conductive microparticles ranges from 1 to 0.1 μm. If the diameter thereof is larger than 0.1 μm, clogging may occur in the nozzles of the liquid droplet discharging head described below. Conversely, the diameter smaller than 1 nm causes an increase in a volume ratio of a coating agent with respect to the conductive microparticles, whereby a ratio of an organic substance in a film obtained is excessively increased.

The dispersion medium is not specifically restricted as long as the medium can disperse the conductive microparticles as mentioned above and does not cause aggregation. For example, besides water, there may be mentioned an alcohol such as methanol, ethanol, propanol or butanol, a hydrocarbon compound such as n-heptane, n-oxtane, decane, dodecane, tetradecane, toluene, xylene, cymene, durene, indene, dipentene, tetrahydronaphthalene, decahydronaphthalene or cyclohexylbenzene, an ether compound such as ethylene glycol dimethyl ether, ethylene glycol diethyl ether, ethylene glycol methyl ethyl ether, diethylene glycol dimethyl ether, diethylene glycol diethyl ether, diethylene glycol methyl ethyl ether, 1,2-dimethoxy ethane, bis (2-methoxy ethyl) ether or p-dioxane, or a polar compound such as propylene carbonate, γ-butyrolactone, N-methyl-2-pyrrolidone, dimethyl formamide, dimethyl sulfoxide or cyclohexanone. Among them, water, alcohols, hydrocarbons and ether compounds are more preferable in terms of the dispersibility of the microparticles, the stability of a dispersion liquid, and easier applicability to the inkjet method. Furthermore, water and hydrocarbon compounds are more preferable dispersion media.

The dispersion liquid that contains the conductive microparticles, preferably, has a surface tension ranging from 0.02 N/m to 0.07 N/m. When the liquid droplet L is discharged by the inkjet method, a surface tension less than 0.02 N/m increases wettability of an ink composition on a nozzle surface, thereby easily causing a flight diversion of the liquid droplet. Meanwhile, a surface tension greater than 0.07 N/m destabilizes a meniscus shape of the droplet at a nozzle tip portion. This makes it difficult to control a discharging amount and a discharging timing of ink. In order to adjust the surface tension, there may be added a minute amount of a surface tension regulator such as a fluorine-based agent, a silicon-based agent, or a nonionic-based agent in the above dispersion liquid in a range that would not significantly reduce the contact angle of the liquid droplet on the substrate. The nonionic surface tension regulator can increase liquid wettability of the substrate and can improve leveling properties of a film, thereby preventing minute unevenness on the film. The above-mentioned surface tension regulator may contain an organic compound such as an alcohol, an ether, an ester or a ketone if necessary.

Preferably, the dispersion liquid has a viscosity ranging from 1 to 50 mPa·s. When discharging droplets of the liquid material by using an inkjet method, the dispersion liquid having the viscosity smaller than 1 mPa·s can cause contamination on a peripheral region of the nozzles due to the material (ink) flown out. On the other hand, if the viscosity is larger than 50 mPa·s, the occurrence frequency of nozzle clogging is increased. This hinders smooth discharging of the liquid droplets.

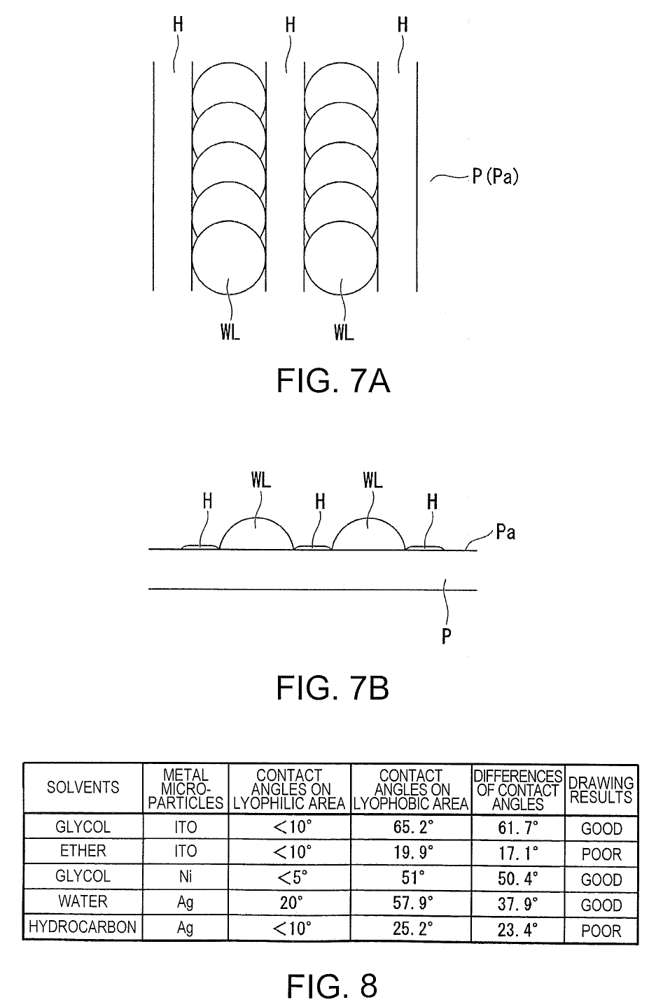

As shown in FIGS. 7A and 7B, on an area between the lyophobic areas H, the liquid droplet discharging head 301 continuously discharges and applies the pattern liquid droplets WL containing the wiring pattern forming material. Specifically, along a length direction (a formation direction of the wiring pattern) of the lyophobic areas H (the lyophilic area Pa), the pattern liquid droplets WL are discharged at a predetermined pitch by relatively moving the liquid droplet discharging head 301 and the substrate P to each other.

In this case, the contact angle of the pattern liquid droplets WL on the surface Pa of the substrate P is 20 degrees or smaller. Thus, the pattern liquid droplets WL applied on the surface are wettingly spread on the area between the lyophobic areas H without being fragmented or forming any bulge. Additionally, the differences of the contact angles (the contrast) of the pattern liquid droplets WL on the lyophobic areas H and the surface Pa are 30 degrees or larger. Thus, the pattern liquid droplets WL are repelled by the lyophobic areas H due to a wettability difference and introduced onto an area of the surface Pa located between the lyophobic areas H to be retained thereon. The contrast of 30 degrees or larger is a sufficient condition. However, given an Example described below, the contrast is more preferably 35 degrees or larger.

The lyophobic areas H, which have the minute thickness of a few to a few tens of nanometers, do not serve as partition walls that define positions of the pattern liquid droplets WL applied. Accordingly, the pattern liquid droplets WL are located on the lyophilic area Pa due to the difference of the contact angle (the difference of the wettability) described above.

Thermal Treatment and/or Optical Treatment Process

Next, the thermal treatment and/or optical treatment process removes the dispersion medium and the coating agent contained in the liquid droplets arranged on the substrate. Namely, in order to facilitate electrical contact between the microparticles, the dispersion medium needs to be completely removed from the liquid material for forming a conductive film arranged on the substrate. Additionally, the coating agent also needs to be removed when the surfaces of the conductive microparticles are coated with the coating agent such as an organic substance to increase dispersibility.

Usually, the thermal treatment and/or the optical treatment is performed in an air atmosphere. However, if needed, the above treatment process may be performed in an atmosphere with an inert gas such as nitrogen, argon or helium. A temperature for the treatment process is appropriately determined based on a boiling point (a vapor pressure) of the dispersion medium, a kind and a pressure of the atmospheric gas, thermal behaviors of the microparticles such as dispersibility and oxidizability, a presence or an absence of the coating agent and an amount of the agent, a heat-resistant temperature of a base material, and the like.

For example, in order to remove the coating agent made of any organic agent, firing at approximately 300° C. is needed. In a case of a plastic substrate, preferably, the firing is performed in a temperature range from a room temperature to 100° C. In the present embodiment, firing is performed at 250° C. for 60 minutes.

The heat treatment and/or the optical treatment may be performed by lamp annealing, other than ordinary heating treatments using a heater such as an electrical furnace. A light source used for the lamp annealing is not specifically restricted. For example, there may be used an infrared lamp, a xenon lamp, a YAG laser, an argon laser, a carbon dioxide gas laser, or an excimer laser such as XeF, XeCl, XeBr, KrF, KrCl, ArF or ArCl. Those light sources are generally applied in an output range of 10 W to 5,000 W, but advantages of the embodiment can be sufficiently achieved in a range of 100 W to 1,000 W.

The thermal treatment and/or the optical treatment serves to secure the electrical contact between the microparticles, thereby achieving a conversion of the liquid material into the conductive film.

Through the series of processes described above, the wiring patterns W1 having the linear shape are formed on the substrate P, as shown in FIG. 4A.

### EXAMPLE

FIG. 8 shows a relationship among contact angles on the lyophobic area H and the lyophilic area Pa, contrasts, and drawing results obtained when dispersion liquids each composed of a solvent and a metal contain glycol and ITO, ether and ITO, glycol and Ni, water and Ag, and hydrocarbon and Ag, as well as the width HA of the lyophobic area H is 100 μm and the width WA of the wiring pattern W is 40 μm.

As shown in a table of FIG. 8, when the contact angle of the liquids on the lyophilic area was 20 degrees or smaller, no bulge occurred. Additionally, when the contact angle of the liquids on the lyophobic area was 50 degrees or larger and the contrast was 30 degrees or larger (preferably, 35 degrees or larger), favorably even wiring patterns were deposited.

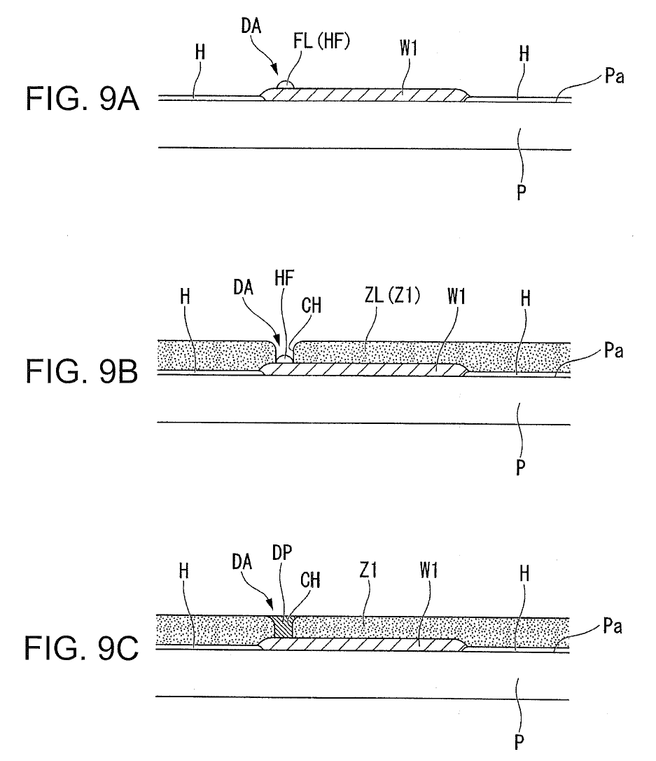

Next will be described steps for forming the contact hole CH and the conducting post DP on the wiring pattern W1 by referring to FIGS. 9A to 9C.

First, as shown in FIG. 9A, on a contact hole forming region (a conducting post forming region) DA of the wiring pattern W1 (where the contact hole CH and the conducting post DP are to be formed later), the liquid droplet discharging head 301 of the apparatus IJ discharges a liquid droplet FL that contains a fluororesin (the lyophobic material) selected among the above-mentioned lyophobic materials and that is lyophobic to a liquid containing a material for forming the insulating layer Z1. The liquid droplet FL applied is dried, so as to form a lyophobic area (a for-insulating-layer lyophobic area) HF against the liquid containing the insulating layer forming material.

A size (a diameter) of the lyophobic area HF corresponds to a size (a diameter) of the conducting post DP that is to be formed later. Thus, the lyophobic area HF is formed with a diameter corresponding to the diameter of the conducting post DP to be formed. In the present embodiment, there is obtained a correlation between a weight of the liquid droplet FL to be discharged and a diameter of the liquid droplet FL that was landed on the wiring pattern W1. For example, when the discharging weight is 2 ng, the diameter of the droplet FL landed is approximately 40 μm, and when the discharging weight is 3 ng, the diameter thereof landed is approximately 65 μm. Then, the correlation is stored in a table. In order to form the lyophobic area HF, the discharging weight is obtained from the table according to the size of the conducting post DP to be formed, thereby discharging the liquid droplet FL with the discharging weight obtained.

Next, as shown in FIG. 9B, the liquid droplet discharging head 301 of the apparatus IJ applies a liquid droplet ZL (hereinafter referred to as an “insulating layer forming liquid droplet ZL” containing the insulating layer forming material so as to cover the wiring pattern W1, except for the lyophobic area HF. In the embodiment, the insulating layer forming material contains a photo-curing material. Specifically, the photo-curing material employed in the embodiment contains a photo-polymerization initiator, and a monomer and/or an oligomer of acrylic acid. In general, the photo-curing material may contain a solvent and a resin dissolved in the solvent. In this case, the photo-curing material may contain a resin that is photosensitive so as to increase a rate of polymerization, or may contain a resin and a photo-polymerization initiator for initiating curing of the resin. As an alternative to those examples, the photo-curing material may contain a monomer that is photo-polymerized to generate an insoluble insulating resin, and a photo-polymerization initiator that initiates photo-polymerization of the monomer. However, the photo-curing material in that case may not need to contain the photo-polymerization initiator, if the monomer has a photo-functional group.

Additionally, a thermosetting polyimide or the like may be used as the insulating layer forming material.

The insulating layer forming liquid droplet ZL applied on the wiring pattern W1 is repelled due to a lyophobic property of the lyophobic areas H formed on the contact hole forming region DA, so that the region DA remains unfilled and open. Thus, the lyophobic area HF is exposed, where the contact hole CH is formed with a size defined by the size of the lyophobic area HF. After that, from a top surface side of the substrate P, ultraviolet light (UV light) as energy light is irradiated to the lyophobic area HF and the insulating layer Z1. The irradiation causes curing of the insulating layer Z1, as well as decomposition and removal of the lyophobic area HF or reduction of the lyophobic property. In a case of the lyophobic area HF made of the fluororesin, the lyophobic property is reduced in accordance with an irradiation time of the UV light. Accordingly, the UV light is irradiated for a time sufficient to reduce the lyophobic property, (for example, for 60 seconds in which the contact angle is 20 degrees or smaller).

Then, using the liquid droplet discharging apparatus IJ, the conductive-material containing liquid droplet, namely in the embodiment, the liquid droplet WL for forming the wiring pattern W1 is applied and dried in the contact hole CH on the conducting-post forming region DA. Thereby, as shown in FIG. 9C, the conducting post DP is formed. In this situation, even if the lyophobic area HF is not completely removed by irradiation of the UV light, there is no problem. The thickness of the fluororesin is the minute amount of a few to a few tens of nanometers. Accordingly, the lyophobic area HF is partially decomposed when the electrical contact between the microparticles of the conductive material due to the thermal treatment or the optical treatment is secured, or the conducting post DP is formed while securing a favorable contact (an electrical continuity) with the wiring pattern W1 due to reactions such as fusions between the microparticles of the conductive material.

In this case, the conducting post DP is exposed on a surface of the insulating layer Z1. Thus, while using the surface of the insulating layer Z1 as a wiring-forming surface, the above-described processes are repeated to produce the multilayered wiring substrate CB including the wiring pattern W2 connected to the conducting post DP.

As described above, in the present embodiment, the insulating layer forming liquid droplet ZL is applied after the lyophobic area HF is formed in advance on the contact hole forming region DA on the wiring pattern W1. Accordingly, even when the liquid droplet ZL is wettingly spread on the wiring pattern W1, the size of the contact hole forming region DA, namely, the size of the contact hole CH and the conducting post DP can be secured and controlled at a predetermined value. As a result, in the multilayered wiring substrate CB produced, the wiring patterns W1, W2 and the conducting post DP are formed with a high precision. In addition, in the present embodiment, the removal of the lyophobic area HF necessary to secure a contact between the conducting post DP and the wiring pattern W1 is performed simultaneously with the curing of the insulating layer Z1 by the irradiation of the UV light. Therefore, individual processes for the removal and the curing are not necessary, which results in productivity improvement.

Additionally, in the embodiment, based on the predetermined table, the diameter of the contact hole CH and the conducting post DP is adjusted by the discharging amount of the lyophobic liquid droplet FL. This enables an easy and rapid selection of the discharging amount of the droplet FL determined in accordance with the diameter of the contact hole and the conducting post DP to be formed, which can further improve productivity.

Furthermore, in the embodiment, also in the formation of the wiring pattern W1, the lyophobic liquid droplet L is applied on the substrate P having the surface Pa as the lyophilic area to form a pattern of the lyophobic area H. Accordingly, it is unnecessary to use an expensive tool such as an exposure device, a photo mask, or a laser light source, thereby preventing cost increase. Furthermore, in the embodiment, adjusting the discharging amount and the discharging pitch of the lyophobic liquid droplet L can facilitate adjustment of the width HA of the lyophobic area H, namely, the width of each wiring pattern W. In particular, the embodiment uses the table indicating the correlation between the discharging amount and the discharging pitch of the liquid droplets with respect to the width HA of the lyophobic area H. This enables an easy and rapid selection of the discharging amount and the discharging pitch of the lyophobic liquid droplets FL determined in accordance with the width WA of the wiring pattern W to be formed. Thus, productivity can be improved.

### Wiring Pattern Forming Method: First Embodiment

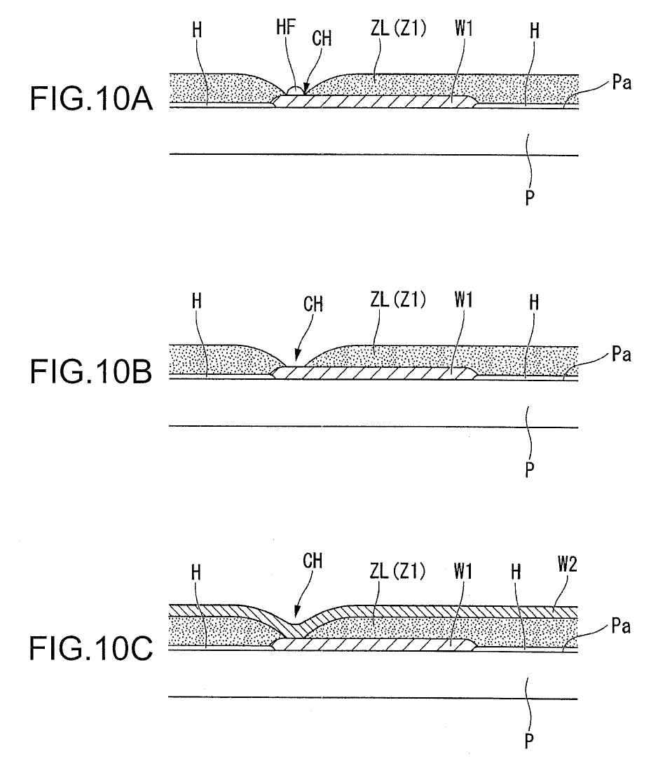

Next, a first embodiment of the wiring pattern forming method will be described with reference to FIGS. 10A to 10C.

As in the situation shown in FIG. 9B, FIG. 10A is a sectional view showing the insulating layer Z1 cured after the contact hole CH is formed by applying the insulating layer forming liquid droplet ZL so as to cover the wiring pattern W1 except for the lyophobic area HF.

In the drawings, the same reference numerals are given to the same elements as those of the embodiment shown in FIGS. 1 to 9C and thus, descriptions thereof will be omitted.

As shown in FIG. 10A, after forming the insulating layer Z1 covering the wiring pattern W1 except for the lyophobic area HF, UV light as energy light is irradiated to the lyophobic area HF and the insulating layer Z1 from the top surface side of the substrate P.

Thereby, the insulating layer Z1 is cured and an upper surface of the layer Z1 is made lyophilic. At the same time, as shown in FIG. 10B, the lyophobic area HF is decomposed and removed, or the lyophobic property is reduced. When the lyophobic area HF is made of a fluororesin, the lyophobic property is reduced in accordance with the irradiation time of the UV light. Thus, the UV light is irradiated for a time sufficient to reduce the lyophobic property.

In addition, before the lyophilic treatment of the insulating layer Z1 described above, another curing process (such as heating treatment) may be performed.

After that, as shown in FIG. 10C, on a region for forming the wiring pattern W2 extended over the contact hole CH and the insulating layer Z1, the liquid droplets WL used to form the wiring pattern W1 are applied by the liquid droplet discharging apparatus IJ, as in the wiring pattern W1. Then, the droplets are dried and fired, so as to form the wiring pattern W2 that is connected to the wiring pattern W1 via the contact hole CH.

Accordingly, the present embodiment also uses the lyophobic area HF to enable high-precision formation of the contact hole CH having the size defined by the lyophobic area HF. Additionally, the wiring patterns W1 and W2 can be easily connected to each other via the contact hole CH.

Furthermore, in the embodiment, an additional process for forming the conducting post is unnecessary, thereby improving production efficiency.

### Wiring Pattern Forming Method: Second Embodiment

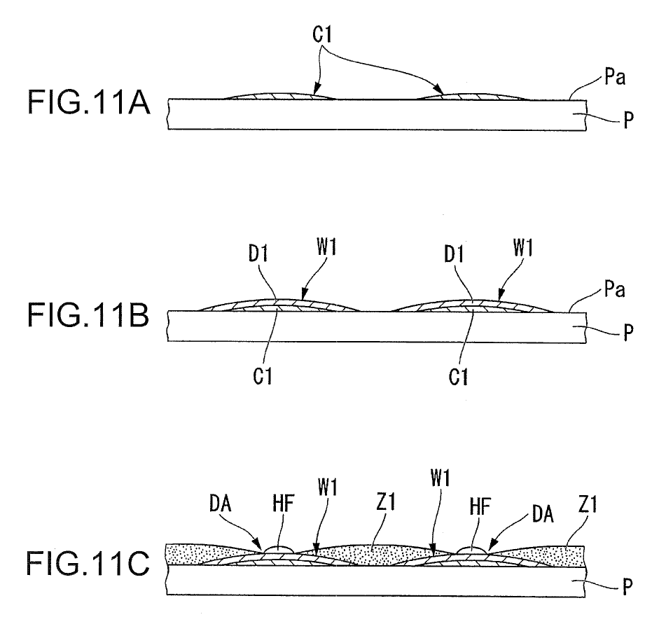

Next, a second embodiment of the wiring pattern forming method will be described with reference to FIGS. 11A to 13C.

In the first embodiment of the wiring pattern forming method, the conductive-material containing liquid droplet is applied to form the wiring patterns W1 and W2. Alternatively, the second embodiment will describe a method for forming the wiring patterns by using plating treatment.

In the drawings, the same reference numerals are given to the same elements as those of the embodiment shown in FIGS. 1 to 9C, and thus, descriptions thereof will be omitted.

As shown in FIG. 11A, for example, a surface cleaning treatment such as UV irradiation is performed on the surface Pa of the substrate P made of polyimide PI, and then, a lyophilic treatment such as O₂ plasma treatment is performed.

Next, using the liquid droplet discharging apparatus IJ, liquid droplets that contain a plating catalyst material are applied and dried (for example, at 100 degrees centigrade for 15 minutes) on the wiring pattern forming region (a first-wiring forming region) of the surface Pa to form a plating catalyst layer C1.

A liquid containing the plating catalyst material may be an organic solvent that contains a catalytic metal, such as Pd, Ni, Ag, Au, Cu, Fe, or Co. Additionally, the liquid may contain a coupling agent to obtain adhesion to the substrate P. The coupling agent may be an Si coupling agent having an amino group. The coupling agent is preferably neutral or acid. More preferably, a neutral coupling agent is used to reduce damage to the liquid droplet discharging head.

The present embodiment uses palladium (Pd) as the plating catalyst material.

Next, electroless plating is performed to deposit a conductive layer D1 on the plating catalyst layer C1, as shown in FIG. 11B. Then, for example, on a hot plate, thermal treatment is performed at 120 degrees centigrade for 30 minutes to form the wiring pattern W1 as the first wiring. As in the liquid containing the plating catalyst material, an electroless plating solution used for the electroless plating is preferably neutral or acid, and more preferably is neutral because of the consideration of damage to the substrate P.

Additionally, the conductive layer D1 may be made of Ag, Ni, Au, Co, Cu, or Pd, for example. The conductive layer may be formed by laminating a plurality of plating layers or by forming an Au plating layer on a Cu plating layer, for example.

The present embodiment uses Cu as the conductive-layer forming material, (namely, copper plating).

Next, using the liquid droplet discharging head 301 of the apparatus IJ, liquid droplets are applied on the contact hole forming region DA on each wiring pattern W1 to be dried thereon. In this case, the liquid droplets are lyophobic to the liquid that contains the insulating layer forming material of the insulating layer Z1. Thereby, there is formed the lyophobic area (the for-insulating-layer lyophobic area) HF against the above liquid. Following that, after covering the wiring patterns W1 except for the lyophobic areas HF, the liquid droplet discharging apparatus IJ applies liquid droplets containing an insulating layer forming material (such as PI, acryl, or epoxy resin) to perform a curing treatment, so as to form the insulating layer Z1. The curing treatment may be heating. For example, the heating treatment is performed at 200 degrees centigrade for 30 minutes when the insulating layer is made of a thermosetting material. In a case of the insulating layer made of a photo-curing material, UV light is irradiated at an intensity of 1,000 to 3,000 mJ/cm², for example.

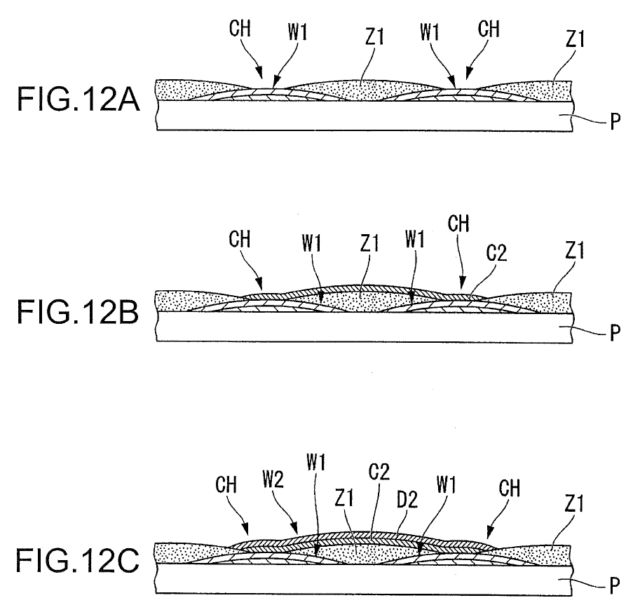

After that, UV irradiation or O₂ plasma treatment is performed on the surface of the substrate P to make the surface of the insulating layer Z1 lyophilic and remove the lyophobic areas HF (the lyophobic property). Thereby, as shown in FIG. 12A, there is formed the contact hole CH, in which the wiring pattern W1 is exposed while being surrounded by the insulating layer Z1.

Then, using the liquid droplet discharging apparatus IJ, as shown in FIG. 12B, the liquid droplets containing the plating catalyst material (Pd) described above are applied in a pattern on a wiring pattern forming region (a second-wiring forming region) extending over the two contact holes CH and the insulating layer Z1 located between the two contact holes CH, and then dried, for example, on the hot plate at 80 degrees centigrade for 5 minutes. Thereby, there is formed a plating catalyst layer C2 that fills the two contact holes CH and is deposited so as to be bridged between the contact holes CH.

After formation of the plating catalyst layer C2, an electroless plating treatment is performed to deposit a conductive layer D2 on the plating catalyst layer C2, as shown in FIG. 12C. Then, a heating treatment is performed on the hot plate at 120 degrees centigrade for 30 minutes to form the wiring pattern W2 as the second wiring by Cu plating.

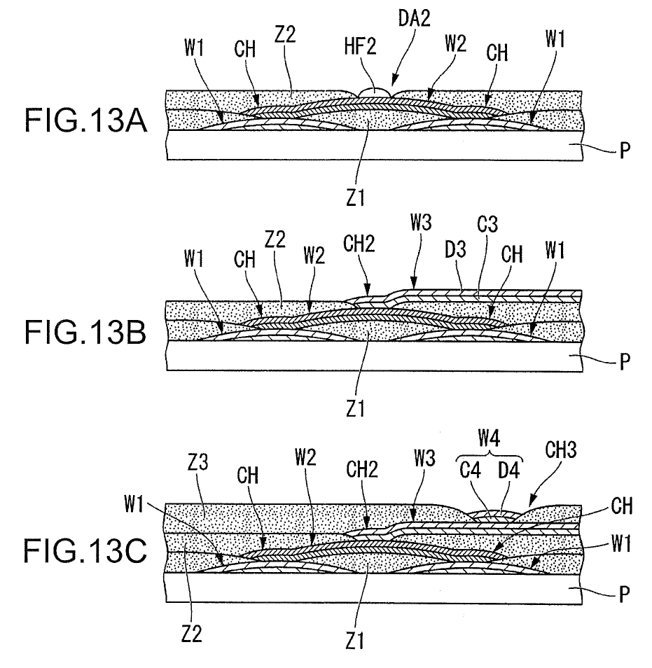

Next, as shown in FIG. 13A, using the liquid droplet discharging head 301 of the apparatus IJ, the liquid droplets lyophobic to the liquid containing the insulating layer forming material are applied on a contact hole forming region DA2 of the wiring pattern W2, and then dried, so as to form a lyophobic area (a for-insulated-layer lyophobic area) HF2 against the above liquid. Then, after covering the wiring pattern W2 except for the lyophobic area HF2, the liquid droplet discharging apparatus IJ applies liquid droplets containing the insulating layer forming material (such as PI, acryl, or epoxy resin) to perform a curing treatment of the insulating layer, so as to form an insulating layer Z2. The curing treatment may be the same as that of the insulating layer Z1.

Then, UV irradiation or O₂ plasma treatment is performed on the surface of the substrate P to make a surface of the insulating layer Z2 lyophilic and remove the lyophobic area HF2 (the lyophobic property). Thereby, there are sequentially performed formation of a contact hole CH2, formation of a plating catalyst layer C3 by pattering application and drying of the liquid droplets containing the plating catalyst material (Pd), and deposition of a conductive film D3 on the plating catalyst layer C3 by the electroless plating treatment. In this manner, as shown in FIG. 13B, there is formed a wiring pattern W3 connected to the wiring pattern W2 via the contact hole CH2.

Next, similarly, as shown in FIG. 13C, there are sequentially performed formation of the lyophobic area, formation of an insulating layer Z3 on a region excluding the lyophobic area, formation of a contact hole CH3 by performing a lyophilic treatment on a surface of the insulating layer Z3 and removing the lyophobic area, formation of a plating catalyst layer C4 by pattering application and drying of the liquid droplets containing the plating catalyst material (Pd), and deposition of a conductive film D4 on the plating catalyst layer C4 by the electroless plating treatment. In this manner, there is formed a wiring pattern (a pad portion) W4 connected to the wiring pattern W3 via the contact hole CH3.

As described above, the embodiment repeats the formation of the lyophobic area, the formation of the insulating layer, the lyophilic treatment of the insulating layer and the removal of the lyophobic area, the formation of the plating catalyst layer, and the formation of the wiring pattern by depositing the conductive layer on the plating catalyst layer to form the contact holes each having the size defined by the lyophobic area, with a high precision. Additionally, there are easily formed the wiring patterns W1 to W4 of a laminate structure connected via the contact holes.

In addition, the present embodiment uses the plating treatment to deposit the wiring patterns W1 to W4 on the regions including filled portions in the contact holes. This enables formation of the wirings that are more elaborate and less electrically resistant, as compared with the liquid droplet discharging method.

Furthermore, in the present embodiment, the lyophobic areas are removed before the patterning application of the liquid droplets containing the plating catalyst material (Pd). However, for example, when the applied lyophobic material is wettingly spread on the wirings formed by the plating treatment and thereby a film thickness is reduced, electrical connection with the wirings exposed in the contact holes may be established without removing the lyophobic areas. Accordingly, removal of the lyophobic areas is not essential. Consequently, the lyophobic areas may be removed if needed, depending on whether the above electrical connection therewith is possible or not.

Multilayered Wiring Substrate

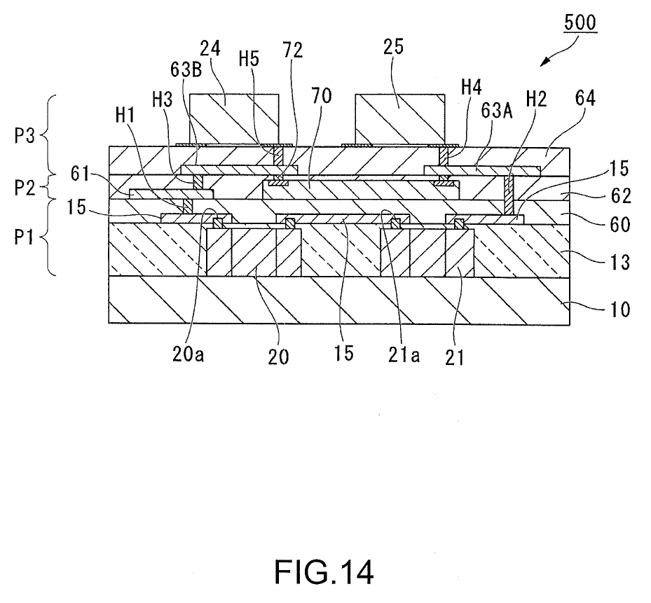

Next, a multilayered wiring substrate according to a second embodiment will be described with reference to FIG. 14.

Hereinafter, a description will be given of an example of the multilayered wiring substrate incorporated in a mobile phone.

A multilayered wiring substrate 500 shown in FIG. 14 includes a base member 10 made of silicon and three wiring layers P1, P2, and P3 laminated on the base member 10.

The base member 10 may be made of glass, quartz glass, a metal plate, or the like, instead of silicon. Additionally, another example of the base member may be a substrate that is made of any one of the above materials and that has an underlying layer including a semiconductor film, a metal film, an insulating film, an organic film, and the like formed thereon.

A wiring layer P1 includes a chip component (an electronic component) 20 having an electrode portion 20a and a chip component (an electronic component) 21 having an electrode portion 21a. The chip components 20 and 21 are embedded in an insulating film (an insulating layer) 13 on which there are deposited wirings 15 connected to the electrode portions 20a and 21a, respectively. The wirings 15 are covered by a first interlayer insulating film 60. In FIG. 14, the wirings 15 located on opposite sides of the substrate 500 are connected to through-holes (conducting posts) H1 and H2, respectively, penetrating through the first interlayer insulating film 60.

The chip components 20 and 21 may be a resistor, a capacitor, an IC chip, or the like. The present embodiment uses the resistor as the chip component 20 and the capacitor as the chip component 21. The chip components 20 and 21 are arranged on the base member 10 in such a manner that the electrode portions 20a and 21a are directed upward.

The electrode portions 20a and 21a are actually approximately flush with upper surfaces of the chip components 20 and 21, although those portions are shown to protrude in the drawing. Alternatively, any protruded portion may be actually formed by discharging a conductive ink by using the liquid droplet discharging method or the like.

The insulating films (the insulating layers) 13 and 60 are formed by applying an insulating ink (an insulating material) by the liquid droplet discharging method using the liquid droplet discharging apparatus IJ and then curing the insulating ink. The insulating ink may contain an acryl photosensitive resin as a material having a photo-curing property and a thermosetting property. The acryl photosensitive resin is cured by applying photo energy and thermal energy, respectively.

The wirings 15 and the through-holes H1 and H2 are formed by discharging the conductive ink by the liquid droplet discharging method using the liquid droplet discharging apparatus IJ. In the present embodiment, the used conductive ink contains silver microparticles.

In addition, a wiring layer P2 includes an IC chip (an electronic component) 70 that is arranged on the first interlayer insulating film 60 and that has first and second external connection terminals 72, a wiring 61 connected to the through-hole H1, a second interlayer insulating film 62 covering the IC chip 70 and the wiring 61, a through-hole H3 connected to the wiring 61 to penetrate through the insulating film 62, a part of the through-hole H2 penetrating through the insulating film 62 as in the through-hole H3.

The second interlayer insulating film 62 is made of the same material as that of the insulating films 13 and 60 and is also formed by the liquid droplet discharging method using the liquid droplet discharging apparatus IJ.

In addition, the wiring 61 is made of the same material as that of the wirings 15, and the through-hole H3 is made of the same material as that of the through-holes H1 and H2. The wirings 61 and the through-hole H3 are also formed by the liquid droplet discharging method using the liquid droplet discharging apparatus IJ.

In addition, a wiring layer P3 includes a wiring 63A formed on the insulating film 62 to be connected to the first terminal 72 of the IC chip 70 and the through-hole H2, a wiring 63B formed on the insulating film 62 to be connected to the second terminal 72 of the IC chip 70 and the through-hole H3, a third interlayer insulating film 64 covering the wirings 63A and 63B, a thorough-hole H4 connected to the wiring 63A to penetrate through the insulating film 64, a thorough-hole H5 connected to the wiring 63B to penetrate through the insulating film 64, a chip component (an electronic component) 24 arranged on the insulating film 64 to be connected to the through-hole H5, and a chip component (an electronic component) 25 arranged on the insulating film 64 to be connected to the through-hole H4.

The third interlayer insulating film 64 is made of the same material as that of the insulating films 13, 60, and 62 and is also formed by the liquid droplet discharging method using the liquid droplet discharging apparatus IJ.

The wirings 63A and 63B are made of the same material as that of the wirings 15, 61, and the through-holes H4 and H5 are made of the same material as that of the through-holes H1, H2, and H3. The wirings 63A, 63B and the through-holes H4, H5 are also formed by the liquid droplet discharging method using the liquid droplet discharging apparatus.

In addition, the chip components 24 and 25 mounted on the substrate 500 are an antenna element and a crystal resonator, respectively.

In the multilayered wiring substrate 500 of the present embodiment, the through-holes H1 to H5 are formed by the contact hole forming method and the conducting post forming method described above. Thus, the size of the through-holes can be maintained and controlled at a predetermined value. As a result, the multilayered wiring substrate 500 can be produced that has the through-holes formed thereon with a high precision.

Furthermore, when the wiring pattern forming method is used to form upper-layer wiring patterns without adding a process for forming the through-holes (the conducting posts), the wiring pattern forming material may be filled in the contact holes to secure electrical connection between the upper-layer wiring patterns and lower-layer wiring patterns.

Switching Element (Thin Film Transistor (TFT) Element)

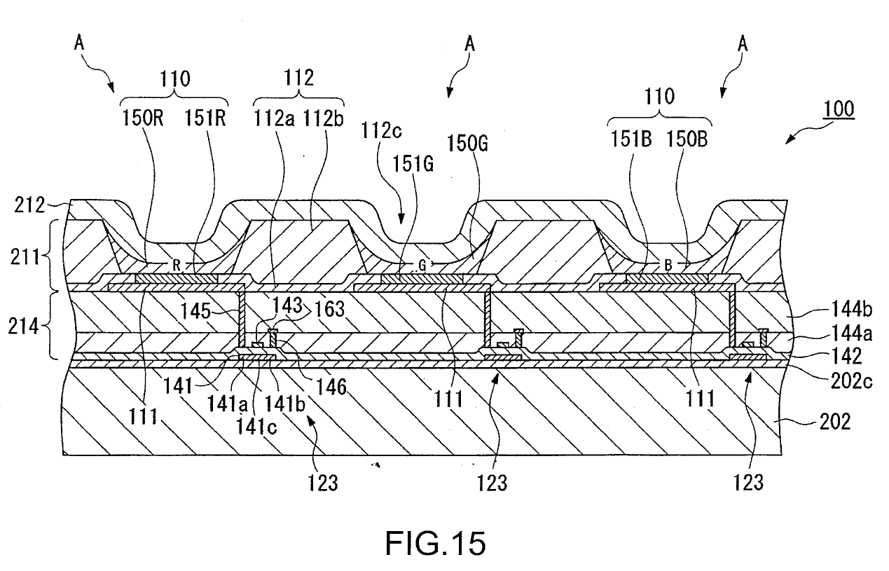

Next will be described an example of a switching element (a TFT element) formed by the contact hole forming method, the conducting post forming method, and the wiring pattern forming method described above, with reference to FIG. 15.

The present embodiment describes the TFT element that is provided in an organic electroluminescent (EL) device. The EL device includes a plurality of pixel regions to emit light with a plurality of luminescent colors in the pixel regions due to mutually different luminescent characteristics.

FIG. 15 is an enlarged diagram of a sectional structure of a display region included in an organic EL device 100. In the drawing, there are shown three pixel regions A. The organic EL device 100 includes a substrate 202, a circuit element section 214 having circuits such as a TFT circuit formed thereon, and an EL element section 211 having an organic layer (a light emitting section) 110 formed thereon. Those sections 214 and 211 are sequentially laminated on the substrate 202.

In the organic EL device 100, light emitted toward the substrate 202 from the organic layer 110 penetrates through the circuit element section 214 and the substrate 202 to be outputted below the substrate 202 (a viewer side), as well as light emitted to a side opposite to the substrate 202 from the organic layer 110 is reflected by a cathode 212, and then penetrates through the circuit element section 214 and the substrate 202 to be outputted below the substrate 202 (the viewer side).

When the cathode 212 is made of a transparent material, it is also possible to emit light through the cathode 212.

In the circuit element section 214, an underlying protective film 202c made of a silicon oxide film is formed on the substrate 202, and an island-shaped semiconductor film 141 made of polycrystalline silicon is formed on the underlying protective film 202c. The semiconductor film 141 has a source region 141a and a drain region 141b that are formed by implantation of high-concentration phosphorus (P) ion, as well as a channel region 141c where no P ion has been implanted.

The circuit element section 214 further includes a transparent gate insulating film 142 that covers the underlying protective film 202c and the semiconductor film 141. On the gate insulating film 142 is formed a gate electrode 143 made of Al, Mo, Ta, Ti, W, or the like. Additionally, on the gate electrode 143 and the gate insulating film 142 are formed transparent first and second interlayer insulating films 144a and 144b. The gate electrode 143 is located at a position corresponding to the channel region 141c of the semiconductor film 141.

In the first and the second interlayer insulating films 144a and 144b, respectively, are formed contact holes 145 and 146, respectively, connected to the source region 141a and the drain region 141b, respectively, of the semiconductor film 141. Each of the contact holes 145 and 146 has a conductive material embedded therein.

On the second interlayer insulating film 144b are formed a plurality of transparent pixel electrodes 111 that are made of indium tin oxide (ITO) and patterned in a predetermined shape. Each of the pixel electrodes 111 is connected to each contact hole 145.

Each of the other contact holes 146 is connected to a power supply line 163.

In this manner, in the circuit element section 214 are formed thin film transistors (TFT elements) 123 connected to the pixel electrodes 111.

The EL element section 211 mainly includes organic layers 110 laminated on the pixel electrodes 111, bank portions 112 provided between the pixel electrodes 111 and the organic layers 110 to partition the organic layers 110, and an opposing electrode as the cathode 212 formed on the organic layers 110.

The pixel electrodes 111 are made of a transparent conductive material such as ITO and are patterned in an approximately rectangular shape when two-dimensionally viewed. Between the pixel electrodes 111 is provided each bank portion 112.

The bank portion 112 includes an inorganic bank layer 112a that is made of SiO₂ or the like and that is formed on a side of the portion 112 opposed to the substrate 202, and an organic bank layer 112b formed on the inorganic bank layer 112a.

The inorganic bank layer 112a is formed so as to extend onto a periphery of each of the pixel electrodes 111 in such a manner that the periphery of the pixel electrode 111 two-dimensionally overlaps with the inorganic bank layer 112a when two-dimensionally viewed. The organic bank layer 112b is also located so as to overlap with a part of the pixel electrode 111 when two-dimensionally viewed.

At the organic bank layers 112 is provided each opening portion 112c. As will be described below, in the opening portion 112c, there is arranged and deposited a film made of a function layer forming material to form the organic layer 110 made of a function layer. The organic bank layer 112b is made of a material having a heat resistance and a solvent resistance, such as acryl resin or polyimide resin.

The organic layers 110 are arranged between the pixel electrodes (anodes) 111 and the opposing electrode (the cathode) 212, whereby the pixel electrodes 111, the organic layers 110, and the opposing electrode 212 are arranged together to constitute organic EL elements. In the present embodiment, to achieve full-color display exhibiting different luminescent characteristics, the organic EL device includes the organic EL elements, each of which serves as a pixel R having red luminescent characteristics, a pixel G having green luminescent characteristics, and a pixel B having blue luminescent characteristics.

In the present embodiment, those three kinds of organic EL elements each include the organic layer 110 including a hole injection/transportation layer (a first organic layer) 151 (151R, 151G, or 151B) and a light-emitting layer (a second organic layer) 150 (150R, 150G, or 150B).

In the embodiment, the contact holes 145 and 146 are formed by the contact hole forming method and the conducting post forming method described above. Additionally, the above-described wiring pattern forming method is used to form the power supply lines 163 connected to the contact holes 146 and the pixel electrodes 111 connected to the contact holes 145.

Accordingly, in the present embodiment, the size of the contact holes can be secured and controlled at a desired value, and the thin film transistor (the TFT element) 123 can be produced that has the contact holes formed with a high precision.

Electronic Apparatus

Next will be described a concrete example of an electronic apparatus according to an embodiment of the invention.

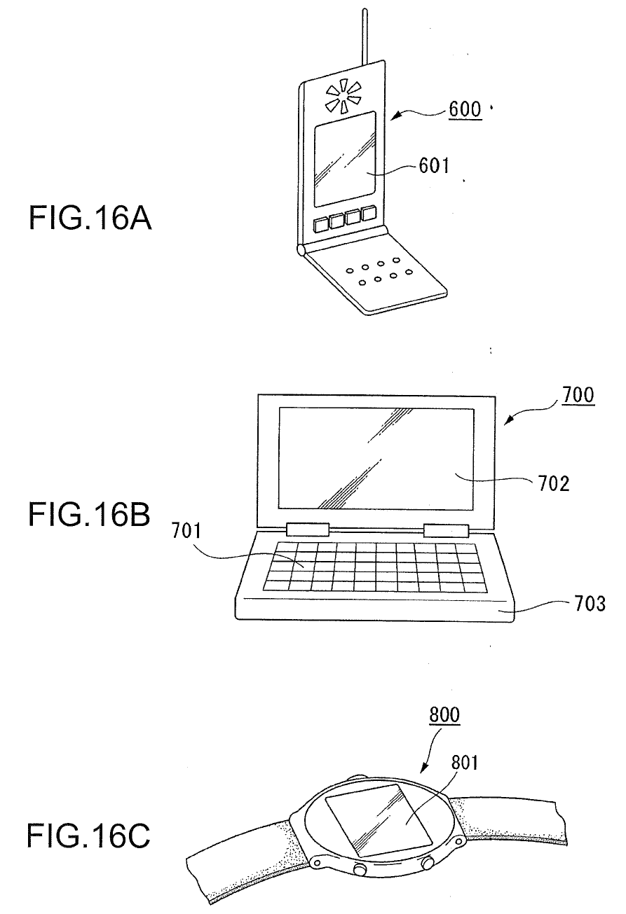

FIG. 16A is a perspective view of an example of a mobile phone. In FIG. 16A, reference numeral 600 denotes a mobile phone's main body including the multilayered wiring substrate of the above embodiment, and reference numeral 601 denotes a liquid crystal display section.

FIG. 16B is a perspective view of an example of a mobile information processor such as a word processor or a personal computer. In FIG. 16B, reference numeral 700 denotes an information processor, reference numeral 701 denotes an input section such as a keyboard, reference numeral 703 denotes an information processor's main body including the multilayered wiring substrate of the above embodiment, and reference numeral 702 denotes a liquid crystal display section.

FIG. 16C is a perspective view of an example of a watch-type electronic apparatus. In FIG. 16C, reference numeral 800 denotes a watch's main body including the multilayered wiring substrate of the above embodiment, and reference numeral 801 denotes a liquid crystal display section.

The electronic apparatuses shown in FIGS. 16A to 16C are produced by the multilayered wiring substrate producing method of the above embodiment. Thus, the apparatuses include wirings and conducting posts formed with a high precision, and thereby can be produced with a high quality.

The above electronic apparatuses of the embodiment each include a liquid crystal device. Alternatively, the embodiment may employ an electronic apparatus including any other electro-optical device such as an organic EL display device or a plasma display device.

Hereinabove, although some preferred embodiments according to the invention have been described with reference to the accompanying drawings, it should be understood that the invention is not restricted to those embodiments and examples as above. The shapes and the combinations of the constituent members used in the above-described embodiments are exemplifications, and thus, various modifications and alterations can be made based on designing requirements, without departing from the spirit and scope of the invention.

Furthermore, in the embodiments described above, in order to increase the lyophilic property of the substrate P, the cleaning treatment is performed as a surface treatment process. Instead of that, for example, a silane coupling agent or a titanium coupling agent lyophilic to a function liquid (the pattern liquid droplets) may be applied on the surface Pa, or titanium oxide microparticles may be applied thereon.

What is claimed is:

1. A method for forming a contact hole, comprising:
forming a lyophobic area by applying a liquid droplet of a lyophobic material on a region for forming a contact hole on a wiring, the lyophobic material being lyophobic to a liquid that contains an insulating layer forming material; and
forming an insulating layer by applying a droplet of the liquid containing the insulating layer forming material so as to cover the wiring except for the lyophobic area, wherein the contact hole formed penetrates through the insulating layer to be connected to the wiring covered by the insulating layer.

2. The method for forming a contact hole according to claim 1, wherein a diameter of the contact hole is adjusted by an amount of the lyophobic liquid droplet applied.

3. The method for forming a contact hole according to claim 1, wherein the lyophobic material includes at least one of a silane compound and a compound having a fluoroalkyl group.

4. The method for forming a contact hole according to claim 3, wherein the silane compound forms a self-assembled film.

5. The method for forming a contact hole according to claim 1, wherein the lyophobic material contains a fluorine compound.

6. The method for forming a contact hole according to claim 1, further comprising forming a plurality of for-wiring lyophobic areas by applying a liquid droplet of a second lyophobic material lyophobic to a liquid containing a wiring forming material on a non-wiring forming region on a wiring forming surface, the wiring forming surface being lyophilic to a droplet of the liquid that contains the wiring forming material, and forming the wiring by applying the liquid droplet containing the wiring forming material on a lyophilic area located between the for-wiring lyophobic areas.

7. A method for forming a conducting post, comprising:
forming a contact hole by the method according to claim 1; and
forming a conducting post by applying a liquid droplet containing a conductive material in the contact hole formed, the conducting post penetrating through an insulating layer to be connected to a wiring covered by the insulating layer.

8. The method for forming a conducting post according to claim 7, further comprising irradiating energy light to the lyophobic area.

9. The method for forming a conducting post according to claim 7, further comprising welding the wiring and the conducting post to each other by heating at least the lyophobic area and the conducting post.

10. A method for forming a wiring pattern, comprising:
forming a contact hole by the method according to claim 1;
curing an insulating layer;
irradiating energy light to a lyophobic area and the insulating layer; and
forming a second wiring extended over the insulating layer and the contact hole, the second wiring being connected to a wiring covered by the insulating layer via the contact hole penetrating through the insulating layer.

11. The method for forming a wiring pattern according to claim 10, wherein the second wiring is formed by applying a liquid droplet containing a conductive material on a second-wiring forming region that extends over the insulting layer and the contact hole.

12. The method for forming a wiring pattern according to claim 10, further comprising forming a plating catalyst layer by applying a liquid droplet containing a plating catalyst material on the second wiring forming region extending over the insulating layer and the contact hole, and forming the second wiring on the plating catalyst layer by plating treatment.

13. A method for producing a multilayered wiring substrate, comprising:
forming a contact hole by the method according to claim 1;
laminating a first wiring and a second wiring via an insulating layer; and
connecting the first and the second wirings to each other via the contact hole.

14. A method for producing an electro-optical device comprising the multilayered wiring substrate producing method according to claim 13.

15. A method for producing an electronic apparatus comprising the multilayered wiring substrate producing method according to claim 13.
